(19) United States
(12) Patent Application Publication
(10) Pub. No.: US 2023/0264596 A1
(43) Pub. Date: Aug. 24, 2023

(54) APPARATUS AND METHOD FOR CONTROLLING POWER OF PARALLEL MULTI PACK MODULE

(71) Applicant: LG ENERGY SOLUTION, LTD., Seoul (KR)

(72) Inventor: Young-Jun KO, Daejeon (KR)

(73) Assignee: LG ENERGY SOLUTION, LTD., Seoul (KR)

(21) Appl. No.: 18/010,259

(22) PCT Filed: Jul. 21, 2021
(86) PCT No.: PCT/KR2021/009448

§ 371 Date: Dec. 14, 2022

(30) Foreign Application Priority Data
Jul. 21, 2020 (KR) 10-2020-0090585

(51) Int. Cl. B60L 58/18; H02J 7/00; B60L 58/14; B60L 58/15; H01M 10/44

(52) U.S. Cl. CPC B60L 58/18; H02J 7/0048; H02J 7/0013; H02J 7/00714; H02J 7/007182; B60L 58/14; B60L 58/15; H01M 10/441

(57) ABSTRACT

Disclosed is an apparatus and method for controlling power of a parallel multi pack module. The apparatus determines a minimum available power of first to nth battery packs based on operation characteristic values of the first to nth battery packs, determines a total power of the parallel multi pack module from the minimum available power and a ratio of a summed current value to a maximum current value among the measured current values of the first to nth battery packs, and transmits the determined total power of the parallel multi pack module to the power management unit, and the power management unit controls the power consumed in a load or the power provided to the parallel multi pack module by a charging device so as not to exceed the total power of the parallel multi pack module.

### TECHNICAL FIELD

The present disclosure relates to a power control apparatus and method, and more particularly, to a power control apparatus and method capable of preventing overcharge or overdischarge of a battery pack having a relatively low resistance in a parallel multi pack module in which a plurality of battery packs are connected in parallel.

The present application claims priority to Korean Patent Application No. 10-2020 0090585 filed on Jul. 21, 2020 in the Republic of Korea, the disclosures of which are incorporated herein by reference.

### BACKGROUND ART

The application field of batteries is gradually increasing not only to mobile devices such as cellular phones, laptop computers, smart phones and smart pads, but also electric-driven vehicles (EVs, HEVs, PHEVs), large-capacity energy storage systems (ESS), or the like.

A battery module mounted to an electric-driven vehicle includes an n number of battery packs connected in parallel to secure a high energy capacity, and each battery pack includes a plurality of battery cells connected in series. Hereinafter, the module in which the n number of battery packs are connected in parallel will be referred to as a parallel multi pack module.

In this specification, the battery cell may include one unit cell or a plurality of unit cells connected in parallel. The unit cell refers to one independent cell that has a negative electrode terminal and a positive electrode terminal and is physically separable. For example, one pouch-type lithium polymer cell may be regarded as a unit cell.

The total power of the parallel multi pack module is determined based on a battery pack with a lowest available power among the battery packs connected in parallel for safety. That is, the value obtained by multiplying a minimum available power among the available power values of the battery packs by the number of battery packs becomes a total power of the parallel multi pack module.

For example, in a parallel multi pack module in which five battery packs are connected in parallel, if the available powers of the five battery packs are 1 kW, 2 kW, 3 kW, 4 kW and 5 kW, respectively, the total power of the parallel multi pack module becomes is 5*1 kW (5 kW).

A management apparatus of the parallel multi pack module provides information on the total power (5 kW) to a control system of the electric-driven vehicle. Then, the control system adaptively distributes the power supplied to an inverter or a DC/DC converter and the power supplied to an ADAS (Advanced Driver Assistance System) unit, which supports functions of lane departure prevention, front collision warning or the like, and an electrical equipment unit so that the power consumed by the electric-driven vehicle does not exceed 5 kW. In this way, the power is distributed within the range of total power provided by the management apparatus of the parallel multi pack module, which is called a power guideline.

Meanwhile, when the total power of the parallel multi pack module is Pₜₒₜₐₗ, a pack power (Pₖ) of each battery pack is automatically distributed by a resistance ratio Rₜₒₜₐₗ/R_{pack,k} between a pack resistance (R_{pack,k}) of the corresponding battery pack and a total resistance (Rₜₒₜₐₗ) of the parallel multi pack module according to the circuit theory. That is, the pack power (P_{pack,k}) of each battery pack is Pₜₒₜₐₗ*Rₜₒₜₐₗ/R_{pack,k}. Here, k is an index of the battery pack.

Since the pack power (P_{pack,k}) is determined not by an available power of the corresponding battery pack but by the total power (Pₜₒₜₐₗ) and the resistance ratio Rₜₒₜₐₗ/R_{pack,k}, as the pack resistance (R_{pack,k}) is lower, the pack power (P_{pack,k}) increases. Accordingly, as the pack power (P_{pack,k}) of the battery pack having a low pack resistance (R_{pack,k}) increases over the available power, the corresponding battery pack may be overcharged or overdischarged.

### DISCLOSURE

### Technical Problem

The present disclosure is designed to solve the problems of the related art, and therefore the present disclosure is directed to providing an apparatus and method for controlling power of a parallel multi pack module, which may prevent a pack power of a battery pack having a lowest resistance from exceeding an available power to cause overcharge or overdischarge, in determining a total power of a parallel multi pack module.

### Technical Solution

In one aspect of the present disclosure, there is provided an apparatus for controlling a power of a parallel multi pack module, comprising: first to n^{th} sensor units configured to measure operation characteristic values including measured current values of first to n^{th} battery packs that are included in the parallel multi pack module and connected to each other in parallel; a power management unit configured to control a power consumed in a load or a power provided to the parallel multi pack module by a charging device to correspond to a total power of the parallel multi pack module; and a multi pack management unit operatively coupled to the first to n^{th} sensor units and the power management unit.

Preferably, the multi pack management unit may be configured to determine a minimum available power of the first to n^{th} battery packs based on the operation characteristic values of the first to n^{th} battery packs received from the first to n^{th} sensor units, determine a total power of the parallel multi pack module from the minimum available power and a ratio of a summed current value to a maximum current value among the measured current values of the first to n^{th} battery packs, and transmit the determined total power of the parallel multi pack module to the power management unit.

Preferably, the power management unit may be configured to control the power consumed in the load or the power provided to the parallel multi pack module by the charging device to correspond to the total power of the parallel multi pack module.

According to an embodiment, the operation characteristic values may further include measured voltage values of the first to n^{th} battery packs. In this embodiment, the multi pack management unit may be configured to determine pack resistances of the first to n^{th} battery packs from the measured current values and the measured voltage values of the first to n^{th} battery packs, determine an available power corresponding to the pack resistance with reference to a predetermined pack resistance-available power look-up table for each battery pack, and determine a minimum value among the available powers as the minimum available power.

According to another embodiment, the multi pack management unit may be configured to periodically receive a measured voltage value and a measured current value of each battery pack from the first to n^{th} sensor units, and determine an average ratio of a voltage change to a current change calculated from the measured current values and the measured voltage values of the first to n^{th} battery packs by means of linear regression analysis as the pack resistance of the first to n^{th} battery packs.

According to still another embodiment, the multi pack management unit may be configured to determine a state of charge (SOC) of the first to n^{th} battery packs based on the operation characteristic value of each battery pack received from the first to n^{th} sensor units, determine an available power corresponding to the SOCs of the first to n^{th} battery packs with reference to a predefined SOC-available power look-up table, and determine a minimum value among the available powers as the minimum available power.

Preferably, the multi pack management unit may be configured to calculate the total power (Pₜₒₜₐₗ) of the parallel multi pack module using the following equation.

Pₜₒₜₐₗ=min(P_{pack,k})*Iₜₒₜₐₗ/max(I_{pack,k}),

where k is an integer from 1 to n; min(P_{pack,k}) corresponds to a minimum available power among the available powers of the first to n^{th} battery packs; Iₜₒₜₐₗ corresponds to a summed current value for the measured current values of the first to n^{th} battery packs; and max(I_{pack,k}) corresponds to a maximum current value among the measured current values of the first to n^{th} battery packs.

According to still another embodiment, the apparatus for controlling power of a parallel multi pack module according to the present disclosure may further comprise a communication unit interposed between the multi pack management unit and the power management unit.

According to still another embodiment, the parallel multi pack module may be mounted to an electric-driven vehicle, and the power management unit may be included in a control system of the electric-driven vehicle.

In another aspect of the present disclosure, there is also provided a battery management system or an electric driving mechanism, comprising the apparatus for controlling power of a parallel multi pack module as described above.

In another aspect of the present disclosure, there is also provided a method for controlling a power of a parallel multi pack module, comprising: (a) providing first to n^{th} sensor units configured to measure operation characteristic values including measured current values of first to n^{th} battery packs that are included in the parallel multi pack module and connected to each other in parallel; (b) determining an available power of each of the first to n^{th} battery packs based on the operation characteristic value of each battery pack received from the first to n^{th} sensor units; (c) determining a minimum available power among the available powers of the first to n^{th} battery packs; (d) determining a total power of the parallel multi pack module from the minimum available power and a ratio of a summed current value to a maximum current value among the measured current values of the first to n^{th} battery packs; and (e) controlling charging or discharging of the first to n^{th} battery packs to correspond to the total power of the parallel multi pack module.

According to an embodiment, the operation characteristic values may further include measured voltage values of the first to n^{th} battery packs, and the step (b) may include: (b1) determining pack resistances of the first to n^{th} battery packs from the measured current values and the measured voltage values of the first to n^{th} battery packs, (b2) determining an available power corresponding to the pack resistance with reference to a predetermined pack resistance-available power look-up table for each battery pack, and (b3) determining a minimum value among the available powers as the minimum available power.

According to another embodiment, the step (b) may include: (1) periodically receiving a measured voltage value and a measured current value of each battery pack from the first to n^{th} sensor units, and (b2) determining an average ratio of a voltage change to a current change calculated from the measured current values and the measured voltage values of the first to n^{th} battery packs by means of linear regression analysis as the pack resistance of the first to n^{th} battery packs.

According to still another embodiment, the step (b) may include: (1) determining a SOC of the first to n^{th} battery packs based on the operation characteristic value of each battery pack received from the first to n^{th} sensor units, (b2) determining an available power corresponding to the SOCs of the first to n^{th} battery packs with reference to a predefined SOC-available power look up table, and (b3) determining a minimum value among the available powers as the minimum available power.

Preferably, in the step (d), the total power (Pₜₒₜₐₗ) of the parallel multi pack module may be calculated using the following equation.

Pₜₒₜₐₗ=min(P_{pack,k})*Iₜₒₜₐₗ/max(I_{pack,k}),

where k is an integer from 1 to n; min(P_{pack,k}) corresponds to a minimum available power among the available powers of the first to n^{th} battery packs; Iₜₒₜₐₗ corresponds to a summed current value for the measured current values of the first to n^{th} battery packs; and max(I_{pack,k}) corresponds to a maximum current value among the measured current values of the first to n^{th} battery packs.

### Advantageous Effects

According to the present disclosure, the total power of the parallel multi pack module is adjusted so that the pack power of the battery pack having a low resistance among the battery packs included in the parallel multi pack module becomes identical to a minimum available power among available powers of the battery packs, thereby preventing the battery pack having a low resistance from being overcharged or overdischarged. As a result, safety and reliability may be improved when the parallel multi pack module is charged or discharged.

### DESCRIPTION OF DRAWINGS

The accompanying drawings illustrate an example embodiment of the present disclosure and together with the foregoing disclosure, serve to provide further understanding of the technical features of the present disclosure, and thus, the present disclosure is not construed as being limited to the details illustrated in the drawings.

FIG. 1 is a block diagram showing a configuration of an apparatus for controlling power of a parallel multi pack module according to an embodiment of the present disclosure.

FIG. 2 shows an example of a pack resistance-available power look-up table according to an embodiment of the present disclosure.

FIG. 3 is a graph showing an example of an I-V profile in determining a pack resistance of a battery pack according to an embodiment of the present disclosure.

FIG. 4 is a flowchart for illustrating a method for controlling power of a parallel multi pack module according to an embodiment of the present disclosure.

FIG. 5 is a block diagram showing a battery management system that includes the apparatus for controlling power of a parallel multi pack module according to an embodiment of the present disclosure.

FIG. 6 is a block diagram showing an electric driving mechanism that includes the apparatus for controlling power of a parallel multi pack module according to an embodiment of the present disclosure.

### EMBODIMENTS

Hereinafter, example embodiments of the present disclosure will be described in detail with reference to the accompanying drawings. Prior to the description, it should be understood that the terms used in the specification and the appended claims should not be construed as limited to general and dictionary meanings but be interpreted based on the meanings and concepts corresponding to technical aspects of the present disclosure on the basis of the principle that the inventor is allowed to define terms appropriately for the best explanation. Therefore, the description proposed herein is just a preferable example for the purpose of illustrations only, not intended to limit the scope of the disclosure, so it should be understood that other equivalents and modifications could be made thereto without departing from the scope of the disclosure.

In the example embodiments described below, a battery cell refers to a lithium secondary battery such as a lithium polymer battery. Here, the lithium secondary battery collectively refers to a secondary battery in which lithium ions act as operating ions during charging and discharging to cause an electrochemical reaction at a positive electrode and a negative electrode.

Meanwhile, even if the name of the secondary battery changes depending on the type of electrolyte or separator used in the lithium secondary battery, the type of packaging material used to package the secondary battery, and the interior or exterior structure of the lithium secondary battery, as long as lithium ions are used as operating ions the secondary battery should be interpreted as being included in the category of the lithium secondary battery.

The present disclosure may also be applied to other secondary batteries other than the lithium secondary battery. Therefore, even if the operating ions are not lithium ions, any secondary battery to which the technical idea of the present disclosure may be applied should be interpreted as being included in the category of the present disclosure regardless of its type.

In addition, it should be noted in advance that the battery cell may refer to one unit cell or a plurality of unit cells connected in parallel.

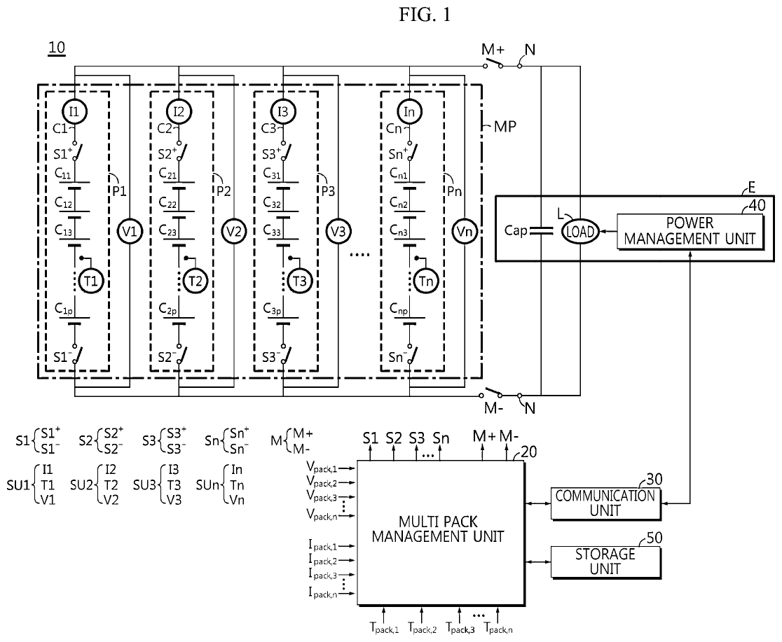

FIG. 1 is a block diagram showing a configuration of an apparatus for controlling power of a parallel multi pack module (hereinafter, also referred to as a power control apparatus) according to an embodiment of the present disclosure.

Referring to FIG. 1, a power control apparatus 10 according to an embodiment of the present disclosure is a device for controlling a power of a parallel multi pack module MP in which a plurality of battery packs P1 to Pn are connected in parallel, and the power control apparatus 10 adaptively controls a total power (Pₜₒₜₐₗ) of the parallel multi pack module MP to prevent some of the battery packs having relatively low pack resistance from being overcharged or overdischarged.

Preferably, the parallel multi pack module MP may include first to n^{th} battery packs P1 to Pn that are connected in parallel through first to n^{th} switch units S1 to Sn.

The parallel multi pack module MP may be connected to a load L through an external switch unit M. The external switch unit M includes an external high-potential switch M+ and an external low-potential switch M−. The external high-potential switch M+ and the external low-potential switch M− may be relay switches or power semiconductor switches, but the present disclosure is not limited thereto.

If the external high-potential switch M+ and the external low-potential switch M− are turned on, the parallel multi pack module MP is electrically connected to the load L. Conversely, when the external high-potential switch M+ and the external low-potential switch M− are turned off, the electrical connection between the parallel multi pack module MP and the load L is released.

The power control apparatus 10 of the parallel multi pack module MP receives a control command for charging start, charging end, discharging start or discharging end from a control device that controls the load L, and controls turn-on or turn-off operation of the external switch unit M according to the control command.

Preferably, the parallel multi pack module MP may be mounted to an electric-driven vehicle E, but the present disclosure is not limited thereto. The electric-driven vehicle E refers to a vehicle that can be driven by a motor, such as an electric vehicle, a plug-in hybrid vehicle or a hybrid electric vehicle.

The load L is a device that receives power from the parallel multi pack module MP, and may be an inverter included in an electric-driven vehicle E as an example. The inverter is a power conversion circuit that is installed at a front end of an electric motor of the electric-driven vehicle E to convert a DC current supplied from the parallel multi pack module MP into a 3-phase AC current and supplies the 3-phase AC current to the electric motor.

The load L may also be a DC/DC converter. The DC/DC converter is a power conversion circuit that converts a voltage of a DC current supplied from the parallel multi pack module MP into a drive voltage of an electric equipment unit of the electric-driven vehicle E or a drive voltage of an ADAS and then applies the converted voltage to the electric equipment unit or the ADAS.

In the present disclosure, the type of the load L is not limited to the inverter or the DC/DC converter, and any device or instrument capable of receiving power from the parallel multi pack module MP may be included in the category of the load L regardless of its type.

In the present disclosure, each of the first to n^{th} battery packs P1 to Pn includes a plurality of battery cells connected in series therein. That is, the first battery pack P1 includes first to p^{th} battery cells C₁₁ to C₁ₚ connected in series. In addition, the second battery pack P2 includes first to p^{th} battery cells C₂₁ to C₂ₚ connected in series. In addition, the third battery pack P3 includes first to p^{th} battery cells C₃₁ to C₃ₚ connected in series. In addition, the n^{th} battery pack Pn includes first to p^{th} battery cells Cₙ₁ to Cₙₚ connected in series. Though fourth to (n−1)^{th} battery packs are not shown in the drawing, they also include a p number of battery cells connected in series in the same manner as the illustrated battery packs.

Each of the first to n^{th} battery packs P1 to Pn includes the switch units S1 to Sn therein. That is, the first battery pack P1 includes a first switch unit S1. In addition, the second battery pack P2 includes a second switch unit S2. In addition, the third battery pack P3 includes a third switch unit S3. In addition, the n^{th} battery pack Pn includes an n^{th} switch unit Sn. Though the fourth to (n−1)^{th} battery packs are not shown in the drawing, they also include a switch unit in the same manner as the illustrated battery packs.

Each of the first to n^{th} switch units S1 to Sn includes a low-potential switch and a high-potential switch. That is, the first switch unit S1 includes a first high-potential switch S1⁺ installed at a high-potential side of the first battery pack P1 and a first low-potential switch S1⁻ installed at a low-potential side of the first battery pack P1. In addition, the second switch unit S2 includes a second high-potential switch S2⁺ installed at a high-potential side of the second battery pack P2 and a second low-potential switch S2⁻ installed at a low-potential side of the second battery pack P2. In addition, the third switch unit S3 includes a third high-potential switch S3⁺ installed at a high-potential side of the third battery pack P3 and a third low-potential switch S3⁻ installed at a low-potential side of the third battery pack P3. In addition, the n^{th} switch unit Sn includes an n^{th} high-potential switch Sn⁺ installed at a high-potential side of the n^{th} battery pack Pn and an n^{th} low-potential switch Sn⁻ installed at a low-potential side of the n^{th} battery pack Pn. Meanwhile, though the fourth to (n−1)^{th} battery packs are not shown in the drawing, they also include a high-potential switch and a low-potential switch in the same manner as the illustrated battery pack. In addition, in each switch unit, any one of the high-potential switch and the low-potential switch may be omitted.

In the following disclosure, when the switch unit is turned on, the low-potential switch may be turned on first and the high-potential switch may be turned on later. Also, when the switch unit is turned off, the high-potential switch may be turned off first and the low-potential switch may be turned off later.

Preferably, the switch employed at the first to n^{th} switch units S1 to Sn may be a relay switch. As an alternative, the first to n^{th} switch units S1 to Sn may be a semiconductor switch such as a MOSFET or a power semiconductor switch, but the present disclosure is not limited thereto.

A capacitor Cap is provided at a front end of the load L. The capacitor Cap is connected in parallel between the parallel multi pack module MP and the load L. The capacitor Cap functions as a filter to prevent a noise current from being applied toward the load L or the parallel multi pack module MP.

The power control apparatus 10 according to the present disclosure includes first to n^{th} current sensors I1 to In. The first to n^{th} current sensors I1 to In are installed on power lines C1 to Cn connected to the first to n^{th} battery packs P1 to Pn, respectively, to measure a current value flowing through the power lines C1 to Cn.

That is, the first current sensor I1 outputs a measured current value (I_{pack,1}) of the first battery pack P1 flowing through the first power line C1 included in the first battery pack P1. In addition, the second current sensor I2 outputs a measured current value (I_{pack,2}) of the second battery pack P2 flowing through the second power line C2 included in the second battery pack P2. In addition, the third current sensor I3 outputs a measured current value (I_{pack,3}) of the third battery pack P3 flowing through the third power line C3 included in the third battery pack P3. In addition, the n^{th} current sensor In outputs a measured current value (I_{pack,n}) of the n^{th} battery pack Pn flowing through the n^{th} power line Cn included in the n^{th} battery pack Pn. Although not shown in the drawing, the fourth to (n−1)^{th} current sensors output measured current values flowing through the fourth to (n−1)^{th} power lines included in the fourth to (n−1)^{th} battery packs, respectively.

In the drawing, it is shown that first to n^{th} current sensors I1 to In are included in the battery packs, respectively. However, in the present disclosure, the first to n^{th} current sensors I1 to In may also be installed outside the battery packs, without limitation.

The first to n^{th} current sensors I1 to In may be Hall sensors. The Hall sensor is a known current sensor that outputs a voltage signal corresponding to the magnitude of a current. In another example, the first to n^{th} current sensors I1 to In may be sense resistors. If the voltage applied to both ends of the sense resistor is measured, the magnitude of current flowing through the sense resistor may be determined using Ohm's law. In other words, if the magnitude of the measured voltage is divided by a known resistance value of the sense resistor, the magnitude of current flowing through the sense resistor may be determined.

The power control apparatus 10 according to an embodiment of the present disclosure also includes first to n^{th} voltage sensors V1 to Vn. The first voltage sensor V1 outputs a measured voltage value (V_{pack,1}) of the first battery pack P1 corresponding to a potential difference between the positive electrode and the negative electrode of the first battery pack P1. In addition, the second voltage sensor V2 outputs a measured voltage value (V_{pack,2}) of the second battery pack P2 corresponding to a potential difference between the positive electrode and the negative electrode of the second battery pack P2. In addition, the third voltage sensor V3 outputs a measured voltage value (V_{pack,3}) of the third battery pack P3 corresponding to a potential difference between the positive electrode and the negative electrode of the third battery pack P3. In addition, the n^{th} voltage sensor Vn outputs a measured voltage value (V_{pack,n}) of the n^{th} battery pack corresponding to a potential difference between the positive electrode and the negative electrode of the n^{th} battery pack Pn. Although not shown in the drawing, the fourth to (n−1)^{th} voltage sensors output measured voltage values of the fourth to (n−1)^{th} battery packs, respectively.

The first to n^{th} voltage sensors V1 to Vn include a voltage measurement circuit such as a differential amplifier circuit. Since the voltage measurement circuit is well known in the art, the voltage measurement circuit will not be described in detail here.

The power control apparatus 10 according to an embodiment of the present disclosure also includes first to n^{th} temperature sensors T1 to Tn. The first temperature sensor T1 outputs a measured temperature value (T_{pack,1}) of the first battery pack P1 indicating a surface temperature of a cell located at a predetermined position, for example at a center, of the first battery pack P1. In addition, the second temperature sensor T2 outputs a measured temperature value (T_{pack,2}) of the second battery pack P2 indicating a surface temperature of a cell located at a predetermined position, for example at a center, of the second battery pack P2. In addition, the third temperature sensor T3 outputs a measured temperature value (T_{pack,3}) of the third battery pack P3 indicating a surface temperature of a cell located at a predetermined position, for example at a center, of the third battery pack P3. In addition, the n^{th} temperature sensor Tn outputs a measured temperature value (T_{pack,n}) of the n^{th} battery pack Pn indicating a surface temperature of a cell located at a predetermined position, for example at a center, of the n^{th} battery pack Pn. Although not shown in the drawing, the fourth to (n−1)^{th} temperature sensors output measured temperature values of the fourth to (n−1)^{th} battery packs, respectively.

In the present disclosure, the first current sensor I1, the first voltage sensor V1 and the first temperature sensor T1 constitute a first sensor unit SU1. In addition, the second current sensor I2, the second voltage sensor V2 and the second temperature sensor T2 constitute a second sensor unit SU2. In addition, third current sensor I3, the third voltage sensor V3 and the third temperature sensor T3 constitute a third sensor unit SU3. In addition, the n^{th} current sensor In, the n^{th} voltage sensor Vn and the n^{th} temperature sensor Tn constitute an n^{th} sensor unit SUn. Although not shown in the drawing, the fourth to (n−1)^{th} sensor units also include a current sensor, a voltage sensor and a temperature sensor, respectively.

In some cases, it is obvious that the first to n^{th} sensor units SU1 to SUn may further include sensors for measuring other operating characteristics of the battery pack in addition to the sensors for measuring current, voltage and temperature.

Preferably, the power control apparatus 10 according to an embodiment of the present disclosure also includes a multi pack management unit 20 operatively coupled to the first to n^{th} switch units S1 to Sn and the first to n^{th} sensor units SU1 to SUn.

The multi pack management unit 20 may be operatively coupled with a power management unit 40 of the electric-driven vehicle E, which manages the power consumed in the load L. As a control element provided to a control system included in the electric-driven vehicle E, the power management unit 40 may adaptively manage the magnitude of power consumed in the load L to be suitable for the total power of the parallel multi pack module MP. Here, the total power means a total discharging power of the parallel multi pack module MP.

In the present disclosure, the load L may be replaced with a charging device. In this case, the power management unit 40 may adaptively manage a charging power supplied to the parallel multi pack module MP to be suitable for the total power of the parallel multi pack module MP. Here, total power means a total charging power provided to the parallel multi pack module MP.

Preferably, the power control apparatus 10 according to an embodiment of the present disclosure may further include a communication unit 30 interposed between the multi pack management unit 20 and the power management unit 40. The communication unit 30 forms a communication interface between the multi pack management unit 20 and the power management unit 40.

In the present disclosure, any known communication interface that supports communication between two different communication media may be used as the communication interface. The communication interface may support wired or wireless communication. Preferably, the communication interface may support CAN communication, daisy chain communication, RS 232 communication, or the like.

If a discharging request is received from the power management unit 40 of the electric-driven vehicle E through communication unit 30, the multi pack management unit 20 turns on the external switch unit M to initiate discharging of the parallel multi pack module MP.

For reference, an M+ signal and an M− signal output from the multi pack management unit 20 represent signals that control the on/off operation of the external high-potential switch M+ and the external low-potential switch M−, respectively. In addition, S1 to Sn signals output from the multi pack management unit 20 represent signals that controls the on/off operation of the first to n^{th} switch units S1 to Sn.

The multi pack management unit 20 also controls the operation of the current sensors I1 to In, the voltage sensors V1 to Vn and the temperature sensors T1 to Tn included in the first to n^{th} sensor units SU1 to SUn while the parallel multi pack module MP is being discharged, and periodically records the operation characteristic value of each battery pack received from the current sensors I1 to In, the voltage sensors V1 to Vn and the temperature sensors T1 to Tn in a storage unit 50.

Here, the operation characteristic value includes measured current values (I_{pack,1} to I_{pack,n}), measured voltage values (V_{pack,1} to V_{pack,n}) and measured temperature values (T_{pack,1} to T_{pack,2}) of the first to n^{th} battery packs P1 to Pn as shown in the figure.

The multi pack management unit 20 may also determine a SOC (State Of Charge) of each battery pack based on the operation characteristic values of the first to n^{th} battery packs P1 to Pn. For example, the multi pack management unit 20 may determine the SOC of the first to n^{th} battery packs P1 to Pn by counting the measured current values (I_{pack,1} to I_{pack,n}) of the first to n^{th} battery packs P1 to Pn over time. The multi pack management unit 20 may measure the OCV of each battery pack using the first to n^{th} voltage sensors V1 to Vn before initiating the discharging of the first to n^{th} battery packs P1 to Pn, and determine an initial SOC of each battery pack by referring to an OCV-SOC look-up table to look up a SOC corresponding to the OCV. In addition, the multi pack management unit 20 may count the measured current values (I_{pack,1} to I_{pack,n}) of the first to n^{th} battery packs P1 to Pn based on the initial SOC over time to calculate the SOC and record the SOC in the storage unit 50. The OCV-SOC look-up table may be defined in advance and recorded in the storage unit 50.

As another example, the multi pack management unit 20 may determine the SOC of the first to n^{th} battery packs P1 to Pn using the extended Kalman filter while the parallel multi pack module MP is being discharged. That is, the multi pack management unit 20 may determine the SOC of the first to n^{th} battery packs P1 to Pn by inputting the operation characteristic value of each battery pack received from the first to n^{th} sensor units SU1 to SUn into the extended Kalman filter coded in software, and record the same in the storage unit 50.

The extended Kalman filter is widely known in the technical field to which the present disclosure belongs. As an example, the extended Kalman filter may be an adaptive algorithm based on an equivalent circuit model or an electrochemical model.

The SOC estimation using the extended Kalman filter is disclosed in, for example, Gregory L. Plett's paper “Extended Kalman filtering for battery management totals of LiPB-based HEV battery packs, Parts 1, 2 and 3” (Journal of Power Source 134, 2004, 252-261), and this paper may be incorporated as a part of this specification.

Of course, the SOC may be determined using other known methods capable of determining SOC by utilizing the operation characteristic value of the battery pack, in addition to the current counting method or the extended Kalman filter described above.

In another aspect, the multi pack management unit 20 may count a measured current value measured in a specific voltage range among a plurality of measured current values for each battery pack recorded in the storage unit 50. In addition, the multi pack management unit 20 may determine a SOH (State Of Health) of each battery pack by referring to a current count value-SOH look-up table in which SOH according to the counted current value of a specific voltage range is defined in advance.

As another example, the multi pack management unit 20 may adaptively determine the SOH of the first to n^{th} battery packs P1 to Pn using the extended Kalman filter while the parallel multi pack module MP is being discharged.

That is, the multi pack management unit 20 may determine the SOH of the first to n^{th} battery packs P1 to Pn by inputting the operation characteristic value of each battery pack received from the first to n^{th} sensor units SU1 to SUn into the extended Kalman filter coded in software.

The SOH estimation using the extended Kalman filter is disclosed in, for example, Korean Patent Registration No. 10-0818520, entitled “Apparatus, method, system and recording medium for estimating a current state and current parameters of an electrochemical cell”, which may be incorporated as part of this specification.

Preferably, the multi pack management unit 20 may determine a pack resistance (R_{pack,k}; k is a battery pack index) of each battery pack based on the operation characteristic values of the first to n^{th} battery packs P1 to Pn and record the same in the storage unit 50.

As an example, the multi pack management unit 20 may determine an I-V profile for each battery pack by means of linear regression analysis by using a plurality of measured current values and a plurality of measured voltage values for each battery pack recorded in the storage unit 50 while the parallel multi pack module MP is being discharged. Here, the plurality of measured current values and the plurality of measured voltage values are sampled for recent measured values based on a present time point. In addition, the multi pack management unit 20 may determine a slope of the I-V profile, calculate an absolute value of the slope as the pack resistance (R_{pack,k}) for each battery pack, and record the same in the storage unit 50. The slope of the I-V profile is an average ratio of the voltage change to the current change and is a factor corresponding to the resistance according to the Ohm's law.

As another example, the multi pack management unit 20 may refer to the present measured temperature value and SOC for each battery pack recorded in the storage unit 50 while the parallel multi pack module MP is being discharged to determine a pack resistance (R_{pack,k}) corresponding to the measured temperature value and SOC by looking up a SOC-temperature-pack resistance look-up table, and record the same in the storage unit 50. Here, the SOC-temperature-pack resistance look-up table has a data structure capable of looking up the pack resistance corresponding to SOC and temperature, and the SOC-temperature-pack resistance look-up table may be defined in advance and recorded in the storage unit 50.

The multi pack management unit 20 also determines an n number of available powers (P_{pack,k}; k is an integer of 1 to n) corresponding to the pack resistance (R_{pack,k}) of each battery pack by using pre-defined correlation information between pack resistance and available power, and determines min(P_{pack,k}) corresponding to a minimum available power among the n number of available powers.

Preferably, the pre-defined correlation may be a pack resistance-available power look-up table capable of looking up the available power according to the pack resistance.

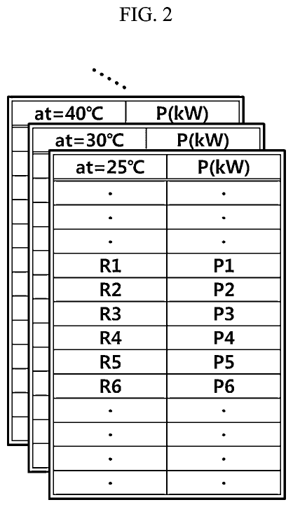

FIG. 2 is a diagram showing an example of a pack resistance-available power look-up table according to an embodiment of the present disclosure.

Referring to FIG. 2, the pack resistance-available power look-up table has a data structure capable of looking up the available power using the pack resistance, and may be defined in advance and recorded in the storage unit 50. It is preferable that the pack resistance-available power look up table is provided independently according to the temperature of the battery pack. In this case, it may be considered that the available power varies according to the temperature of the battery pack. Preferably, the multi pack management unit 20 may identify the pack resistance-available power look-up table that is to be looked up using the measured temperature value of each battery pack, and determine the available power (P_{pack,k}) corresponding to the pack resistance (R_{pack,k}) using the identified look-up table.

More preferably, the pack resistance-available power look-up table may be provided independently for each SOH and temperature of the battery pack. In this case, it may be considered that the available power varies according to the temperature and SOH of the battery pack. Preferably, the multi pack management unit 20 may identify the pack resistance-available power look-up table that is to be looked up using the measured temperature value and SOH of each battery pack, and determine the available power (P_{pack,k}) corresponding to the pack resistance (R_{pack,k}) of each battery pack using the identified look-up table.

In another aspect, the multi pack management unit 20 may determine the available power for each battery pack using the I-V profile generated when determining the pack resistance (R_{pack,k}) of each battery pack.

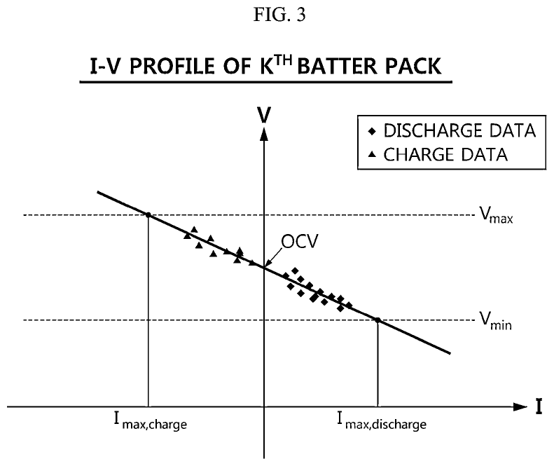

FIG. 3 is a graph showing an example of an I-V profile according to an embodiment of the present disclosure.

Referring to FIG. 3, the voltage at an intersection point where the I-V profile meets a V axis is an OCV (Open Circuit Voltage) corresponding to the SOC of the battery pack. Diamond dot marks indicate a plurality of measured voltage values and a plurality of measured current values measured when the parallel multi pack module MP is being discharged. Also, triangle dot marks indicate a plurality of measured voltage values and a plurality of measured current values measured when the parallel multi pack module MP is being charged. The I-V profile is a straight line generated by means of linear regression analysis for the plurality of measured voltage values and the plurality of measured current values. When the battery pack is being discharged, the measured current value is a positive value, and when the battery pack is being charged, the measured current value is a negative value. In addition, the absolute value of the slope of the I-V profile corresponds to the pack resistance (R_{pack,k}) of the battery pack.

When the parallel multi pack module MP is being discharged, the multi pack management unit 20 may determine a current value at an intersection where the I-V profile meets a straight line V=Vₘᵢₙ representing a discharge lower limit voltage as a maximum discharge current (I_{max,discharge}), and determine Vₘᵢₙ*|I_{max,discharge}| as the available power of the battery pack.

Meanwhile, when the parallel multi pack module MP is being charged, the multi pack management unit 20 may determine a current value at an intersection where the I-V profile generated to determine the pack resistance (R_{pack,k}) of each battery pack meets the line V=Vₘₐₓ representing a charge upper limit voltage as a maximum charge current (I_{max,charge}), and determine Vₘₐₓ*|I_{max,charge}| as the available power of the battery pack.

The multi pack management unit 20 determines the available powers (P_{pack,k}; k is 1 to n) of the first to n^{th} battery packs P1 to Pn, then determines a minimum available power among the n number of available powers, and records the same in the storage unit 50.

The multi pack management unit 20 also adaptively determines the total power of the parallel multi pack module MP so that the pack power of the battery pack having a lowest pack resistance is identical to the minimum available power, and records the same in the storage unit 50.

Specifically, the multi pack management unit 20 may determine the total power (Pₜₒₜₐₗ) of the parallel multi pack module MP using Equation 1 below.

$${P}_{total} = min ( {P}_{pack , k} ) * {I}_{total} / max ( {I}_{pack , k} ) \qquad < Equation 1 >$$

$${I}_{total} = {{\sum }^{n}}_{k = 1} {I}_{pack , k}$$

Here, k is an integer from 1 to n.

n is the number of battery packs.

Pₜₒₜₐₗ is the total power of the parallel multi pack module MP.

P_{pack,k} is an available power of a k^{th} battery pack.

I_{pack,k} is a measured current value of a k^{th} battery pack.

Iₜₒₜₐₗ is a current value of the parallel multi pack module MP. Iₜₒₜₐₗ is a summed current value obtained by adding all measured current values (I_{pack,1} to I_{pack,n}) of the first to n^{th} battery packs P1 to Pn included in the parallel multi pack module MP.

max( ) is a function that returns a maximum value among a plurality of input variables. Therefore, max(I_{pack,k}) corresponds to a maximum current value among the measured current values (I_{pack,1} to I_{pack,n}) of the first to n^{th} battery packs P1 to Pn included in the parallel multi pack module MP.

If the total power (Pₜₒₜₐₗ) of the parallel multi pack module MP is determined according to Equation 1, an actual pack power of the battery pack having a lowest pack resistance (R_{pack,k}) becomes equal to the minimum available power min(P_{pack,k}) as described below. Here, the pack power means an actual power that each battery pack can provide when the parallel multi pack module MP is discharged, and it is a factor determined by the ratio of the pack resistance of each battery pack to the total resistance of the parallel multi pack module MP.

First, among the factors (terms) of Equation 1, if the denominator and numerator of ‘Iₜₒₜₐₗ/max(I_{pack,k})’ are multiplied by ‘V/{Iₜₒₜₐₗ*max(I_{pack,k})}’, this may be expressed as in Equation 2 below.

$$\begin{matrix}{P}_{total} = min ( {P}_{pack , k} ) * {I}_{t otal} / max ( {I}_{pack , k} ) \\ = min ( {P}_{p a c k , k} ) * \{ V / max ( {I}_{p a c k , k} ) \} / \{ V / {I}_{total} \}\end{matrix} \qquad < Equation 2 >$$

In Equation 2, V is an output voltage of the parallel multi pack module MP, and it may be substantially the same as the measured voltage values (V_{pack,1} to V_{pack,n}) of the first to n^{th} battery packs P1 to Pn when the parallel multi pack module MP is being discharged or charged.

In Equation 2, ‘V/max(I_{pack,k})’ corresponds to min(R_{pack,k}), which is a minimum resistance among the pack resistances of the first to n^{th} battery packs P1 to Pn. This is because a maximum current flows through a battery pack having a minimum resistance when the output voltage of the parallel multi pack module MP is V. In addition, ‘V/Iₜₒₜₐₗ’ corresponds to Rₜₒₜₐₗ, which is a total resistance of the parallel multi pack module MP. Therefore, Equation 2 may be converted into Equation 3.

Pₜₒₜₐₗ=min(P_{pack,k})*min(R_{pack,k})/Rₜₒₜₐₗ <Equation 3>

Rₜₒₜₐₗ is an equivalent resistance to the pack resistances of the first to n^{th} battery packs P1 to Pn connected in parallel, and corresponds to a total resistance of the parallel multi pack module MP. The pack resistances (R_{pack,k}) of the first to n^{th} battery packs P1 to Pn and the total resistance Rₜₒₜₐₗ of the -parallel multi pack module MP satisfy Equation 4 below.

$${R}_{total}^{- 1} = {\sum }_{k = 1}^{n} {R}_{pack , k}^{- 1} \qquad < Equation 4 >$$

Meanwhile, Equation 3 may be converted into an equation including the total power min(P_{pack,k})*n of the parallel multi pack module MP determined according to the prior art as in Equation 5 below.

$$\begin{matrix}{P}_{total} = min ( {P}_{pack , k} ) * min ( {R}_{pack , k} ) / {R}_{t otal} \\ = [ min ( {P}_{pack , k} ) * n ] * min ( {P}_{pack , k} ) * min ( {R}_{pack , k} ) / \{ [ min ( {P}_{p a c k , k} ) * n ] * {R}_{total} \} \\ = [ min ( {P}_{pack , k} ) * n ] * min ( {P}_{pack , k} ) / max ( {P}_{pack , k} )\end{matrix} \qquad < Equation 5 >$$

In the second line of Equation 5 above, “min(R_{pack,k})/{[min(P_{pack,k})*n]*Rₜₒₜₐₗ}” corresponds to a reciprocal of a pack power calculated for the battery pack having a lowest resistance among the first to n^{th} battery packs P1 to Pn.

It is because the total power of the parallel multi pack module MP calculated according to the prior art is “min(P_{pack,k})*n”, which is obtained by multiplying the minimum value “min(P_{pack,k})” among the available powers of the first to n^{th} battery packs P1 to Pn by the number n of battery packs, and the pack power of the battery pack having a lowest resistance corresponds to a value obtained by multiplying a resistance ratio “Rₜₒₜₐₗ/min(R_{pack,k})” by the total power “min(P_{pack,k})*n” calculated using the available powers.

Since the pack power of the battery pack having a lowest resistance has a maximum value among the n number of pack powers, “min(R_{pack,k})/{[min(P_{pack,k})*n]*Rₜₒₜₐₗ}” in the second line of Equation 5 may be replaced with max(P_{pack,k})⁻¹, as finally arranged in the third line.

Here, the pack power means an actual power of each battery pack when the parallel multi pack module MP is discharged. The actual power may be calculated by multiplying the total power (Pₜₒₜₐₗ) of the parallel multi pack module MP by the ratio (Rₜₒₜₐₗ/R_{pack,k}) of the pack resistance (R_{pack,k}) of each battery pack to the total resistance (Rₜₒₜₐₗ) of the parallel multi pack module MP.

Seeing Equation 5, the total power (Pₜₒₜₐₗ) of the parallel multi pack module MP determined according to an embodiment of the present disclosure corresponds to a value obtained by multiplying the total power “min(P_{pack,k})*n” determined from the minimum available power of the first to n^{th} battery packs P1 to Pn by an attenuation factor, namely “min(P_{pack,k})/max(P_{pack,k})”. Here, “min(P_{pack,k})/max(P_{pack,k})” is a relative ratio between a maximum value and a minimum value among the available powers of the first to n^{th} battery packs P1 to Pn and thus is always smaller than 1. Therefore, the total power of the parallel multi pack module MP determined according to the present disclosure is smaller than the total power determined from the minimum available power of the first to n^{th} battery packs P1 to Pn by [min(P_{pack,k})*n]*[1-min(P_{pack,k})/max(P_{pack,k})].

If the pack power (P_{pack,Rmin}) of the battery pack having a lowest pack resistance is calculated using the total power (Pₜₒₜₐₗ) determined by Equation 5, it is equal to the minimum available power among the available powers of the first to n^{th} battery packs P1 to Pn as in Equation 6. Therefore, it is possible to fundamentally prevent the phenomenon that the battery pack having a lowest pack resistance is overcharged or overdischarged while the parallel multi pack module MP is being discharged.

$$\begin{matrix}{P}_{p ack , R min} = {P}_{total} * {R}_{t otal} / min ( {R}_{pack , k} ) \\ = \{ min ( {P}_{pack , k} ) * min ( {R}_{pack , k} ) / {R}_{total} \} * \{ {R}_{total} / min ( {R}_{pack , k} ) \} \\ = min ( {P}_{pack , k} )\end{matrix} \qquad < Equation 6 >$$

According to the present disclosure, when the total power (Pₜₒₜₐₗ) of the parallel multi pack module MP is determined according to Equation 1, the pack power (P_{pack,Rmin}) of the battery pack having a lowest pack resistance (R_{pack,k}) becomes equal to min(P_{pack,k}), which is a minimum available power.

In addition, in Equation 1, since the total power (Pₜₒₜₐₗ) of the parallel multi pack module MP is determined by Iₜₒₜₐₗ, which is a summed current value of the measured current values (I_{pack,1} to I_{pack,n}) of the first to n^{th} battery packs P1 to Pn, and max(I_{pack,k}), which is a maximum value of the measured current values (I_{pack,1} to I_{pack,n}), and the measured current values (I_{pack,1} to I_{pack,n}) are accurately measured through the first to n^{th} current sensors I1 to In, there is an advantage that the total power (Pₜₒₜₐₗ) may be reliably determined through simple calculation.

Meanwhile, in Equation 1, min(P_{pack,k}) corresponding to the minimum available power of the first to n^{th} battery packs P1 to Pn may be determined with reference to a SOC-available power look-up table. That is, after determining the SOCs of the first to n^{th} battery packs P1 to Pn, the available power (P_{pack,k}) corresponding to the SOC of each battery pack may be mapped with reference to the SOC-available power look-up table, and a minimum value among the mapped available powers may be determined as min(P_{pack,k}). Here, the SOC-available power look-up table is a look-up table capable of mapping an available power according to the SOCs of the first to n^{th} battery packs P1 to Pn, and may be predefined and recorded in the storage unit 50 in advance.

If min(P_{pack,k}) is determined with reference to the SOC-available power look-up table, this may replace the process of determining the pack resistances (R_{pack,k}) of the first to n^{th} battery packs P1 to Pn using the I-V profile and determining an available power (P_{pack,k}) from the pack resistance (R_{pack,k}), thereby reducing the computational load for determining the minimum available power min(P_{pack,k}).

After determining the total power (Pₜₒₜₐₗ), the multi pack management unit 20 may transmit information on the total power (Pₜₒₜₐₗ) to the power management unit 40 of the electric-driven vehicle E through the communication unit 30.

Then, the power management unit 40 controls charging or discharging of the parallel multi pack module MP so that the power of the parallel multi pack module MP does not exceed the total power (Pₜₒₜₐₗ) determined by Equation 1. That is, the power management unit 40 controls the power consumption so that the power consumed in the load L does not exceed the total power (Pₜₒₜₐₗ) determined by Equation 1.

Specifically, the power management unit 40 adaptively distributes the power supplied to an inverter or a DC/DC converter corresponding to the load L and the power supplied to an electrical equipment unit and an ADAS (Advanced Driver Assistance System) unit, which supports functions of lane departure prevention, front collision warning or the like, so as not to exceed the total power (Pₜₒₜₐₗ) of the parallel multi pack module MP.

Meanwhile, if the load L is replaced by a charging device, the power management unit 40 may adaptively adjust the magnitude of the charging voltage and the charging current provided to the parallel multi pack module MP so as not to exceed the total power (Pₜₒₜₐₗ) determined by Equation 1 while the parallel multi pack module MP is being charged using the charging device.

Therefore, it is possible to prevent a battery pack having a low resistance among the battery packs of the parallel multi pack module MP from being overcharged or overdischarged, like the prior art.

In the present disclosure, there is no particular limitation on the type of the storage unit 50 as long as it is a storage medium capable of recording and erasing information. As an example, the storage unit 50 may be a RAM, a ROM, an EEPROM, a register, or a flash memory. The storage unit 50 may also be electrically connected to the multi pack management unit 20 through, for example, a data bus so as to be accessed by the multi pack management unit 20.

The storage unit 50 also stores and/or updates and/or erases and/or transmits a program including various control logics performed by the multi pack management unit 20, and/or data generated when the control logic is executed and look-up tables and parameters defined in advance. The storage unit 50 may be logically divided into two or more parts and may be included in the multi pack management unit 20 without limitation.

In the present disclosure, the multi pack management unit 20 and/or the power management unit 40 may optionally include a processor, an application-specific integrated circuit (ASIC), another chipset, a logic circuit, a register, a communication modem, a data processing device, or the like, known in the art to execute the various control logics described above. In addition, when the control logic is implemented in software, the multi pack management unit 20 and/or the power management unit 40 may be implemented as a set of program modules. At this time, the program module may be stored in a memory and executed by a processor. The memory may be provided inside or outside the processor and be connected to the processor through various well-known computer components. Also, the memory may be included in the storage unit 50 of the present disclosure. In addition, the memory refers to a device in which information is stored, regardless of the type of device, and does not refer to a specific memory device.

In addition, one or more of the various control logics of the multi pack management unit 20 and/or the power management unit 40 may be combined, and the combined control logics may be written in a computer-readable code system and recorded in a computer-readable recording medium. The recording medium is not particularly limited as long as it is accessible by a processor included in a computer. As an example, the storage medium includes at least one selected from the group consisting of a ROM, a RAM, a register, a CD-ROM, a magnetic tape, a hard disk, a floppy disk and an optical data recording device. The code scheme may be distributed to a networked computer to be stored and executed therein. In addition, functional programs, codes and code segments for implementing the combined control logics may be easily inferred by programmers in the art to which the present disclosure belongs.

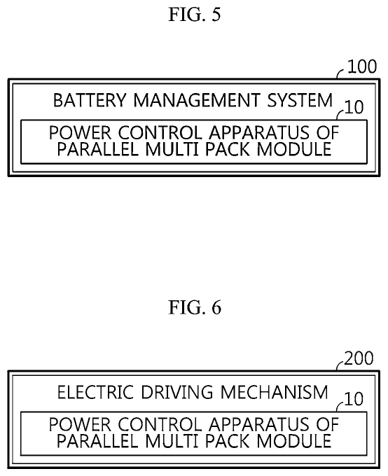

The power control apparatus 10 according to an embodiment of the present disclosure may be included in a battery management system 100 as shown in FIG. 5. The battery management system 100 controls the overall operation related to charging and discharging of a battery, and is a computing system called a battery management system (BMS) in the art.

In addition, the power control apparatus 10 according to an embodiment of the present disclosure may be mounted to various types of electric driving mechanism 200 as shown in FIG. 6, in addition to the electric-driven vehicle E.

The electric driving mechanism 200 may be an electric power device movable by electricity, such as an electric bicycle, an electric motorcycle, an electric train, an electric ship and an electric plane, or a power tool having a motor, such as an electric drill and an electric grinder.

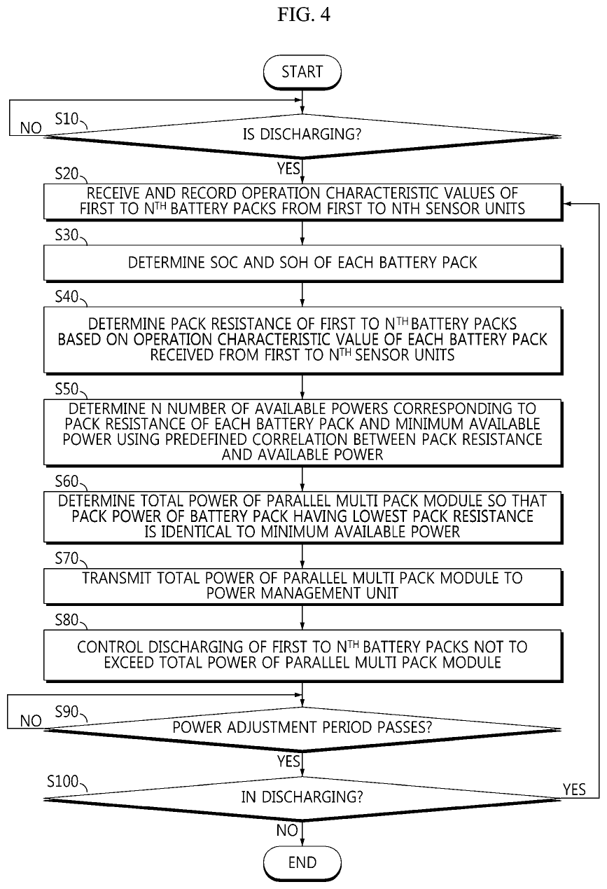

FIG. 4 is a flowchart for illustrating a method for controlling power of a parallel multi pack module MP according to an embodiment of the present disclosure.

As shown in FIG. 4, in Step S10, the multi pack management unit 20 determines whether the parallel multi pack module MP is in a discharge state. To this end, the multi pack management unit 20 may monitor measured current values (I_{pack,1} to I_{pack,n}) measured using the first to n^{th} current sensors I1 to In. If the measured current values (I_{pack,1} to I_{pack,n}) are positive rather than 0, it may be determined that the parallel multi pack module MP is being discharged. If the determination result of Step S10 is YES, the multi pack management unit 20 proceeds to Step S20.

In Step S20, the multi pack management unit 20 controls the first to n^{th} sensor units SU1 to SUn to receive the operation characteristic values of the first to n^{th} battery packs P1 to Pn from the first to n^{th} sensor units SU1 to SUn, and records the same in the storage unit 50.

In the present disclosure, the operation characteristic value includes measured voltage values (V_{pack,1} to V_{pack,n}), measured current values (I_{pack,1} to I_{pack,n}) and measured temperature values (T_{pack,1} to T_{pack,n}) of each battery pack. Step S30 proceeds after Step S20.

In Step S30, the multi pack management unit 20 determines SOC and SOH of each battery pack. The method of determining SOC and SOH has already been described above. Step S40 proceeds after Step S30.

In Step S40, the multi pack management unit 20 determines the pack resistances (R_{pack,k}) of the first to n^{th} battery packs P1 to Pn, respectively, based on the operation characteristic value of each battery pack received from the first to n^{th} sensor units SU1 to SUn.

Preferably, the multi pack management unit 20 may generate an I-V profile for a plurality of measured voltage values and a plurality of measured current values recently sampled based on the present time point by means of linear regression analysis, and calculate the pack resistance (R_{pack,k}) of each battery pack from a slope of the I-V profile. Step S50 proceeds after Step S40.

In Step S50, the multi pack management unit 20 determines an n number of available powers (P_{pack,k}) corresponding to the pack resistance (R_{pack,k}) of each battery pack using a pre-defined correlation between pack resistance and available power, and determines a minimum available power (min(P_{pack,k})) among the n number of available powers.

In an example, the multi pack management unit 20 may look up an available power (P_{pack,k}) corresponding to the pack resistance (R_{pack,k}) of each battery pack using the pack resistance-available power look-up table recorded in advance in the storage unit 50.

Preferably, in determining the available power (P_{pack,k}) of each battery pack, the multi pack management unit 20 may identify the pack resistance-available power look-up table corresponding to the measured temperature value and SOH of the corresponding battery pack and look up an available power (P_{pack,k}) corresponding to the pack resistance (R_{pack,k}) using the identified pack resistance-available power look-up table.

In another example, the multi pack management unit 20 may determine a current at a point where the I-V profile used in calculating the pack resistance (R_{pack,k}) of each battery pack intersects with the straight line V=Vₘᵢₙ corresponding to a discharge lower limit voltage as a maximum discharge current I_{max,discharge}, and determine a value calculated by the equation V=Vₘᵢₙ*|I_{max,discharge}| as the available power (P_{pack,k}).

In another example, the multi pack management unit 20 may determine an available power (P_{pack,k}) of each battery pack by looking up an available power corresponding to the SOC of each battery pack with reference to the SOC-available power look-up table using the SOC of each battery pack. The SOC-available power look-up table may be defined according to the SOH and temperature of the battery pack. In this case, the multi pack management unit 20 may identify the SOC-available power look-up table corresponding to the SOH and the measured temperature value of each battery pack and may determine an available power of each battery pack with reference to the identified look-up table.

Step S60 proceeds after Step S50.

In Step S60, the multi pack management unit 20 determines the total power (Pₜₒₜₐₗ) of the parallel multi pack module so that the pack power of the battery pack having a lowest pack resistance (R_{pack,k}) is identical to the minimum available power using Equation 1 above. At this time, the multi pack management unit 20 may determine the total power (Pₜₒₜₐₗ) using the maximum value max(I_{pack,k}) among the measured current values (I_{pack,1} to I_{pack,n}) of the first to n^{th} battery packs P1 to Pn and the summed current value (Iₜₒₜₐₗ) of the measured current values (I_{pack,1} to I_{pack,n}). Since the measured current values (I_{pack,1} to I_{pack,n}) may be accurately measured using the first to n^{th} current sensors I1 to In, the total power (Pₜₒₜₐₗ) attenuated than the total power determined by the prior art may be reliably measured. Here, the total power Pₜₒₜₐₗ has a magnitude attenuated by [min(P_{pack,k})*n]*[1-min(P_{pack,k})/max(P_{pack,k})] compared to the total power calculated according to the prior art. Step S70 proceeds after Step S60.

In Step S70, the multi pack management unit 20 transmits the total power (Pₜₒₜₐₗ) of the parallel multi pack module MP to the power management unit 40 of the electric-driven vehicle E through the communication unit 30. Step S80 proceeds after Step S70.

In Step S80, the power management unit 40 controls discharging of the parallel multi pack module MP so that the power of the parallel multi pack module MP does not exceed the total power (Pₜₒₜₐₗ) determined by Equation 1.

That is, the power management unit 40 controls the power consumption so that the power consumed in the load L does not exceed the total power (Pₜₒₜₐₗ) determined by Equation 1.

Specifically, the power management unit 40 adaptively distributes the power supplied to an inverter or a DC/DC converter corresponding to the load L and the power supplied to an electrical equipment unit and an ADAS (Advanced Driver Assistance System) unit, which supports functions of lane departure prevention, front collision warning or the like, so as not to exceed the total power (Pₜₒₜₐₗ) of the parallel multi pack module MP determined by Equation 1.

As a result, it is possible to fundamentally prevent the conventional problem that a battery pack having a low resistance among the battery packs of the parallel multi pack module MP is overcharged or overdischarged while the parallel multi pack module MP is being discharged.

Step S90 proceeds after Step S80.

In Step S90, the multi pack management unit 20 determines whether a preset power adjustment period passes. The power adjustment period is several ten msec to several seconds. If the determination result of Step S90 is NO, the multi pack management unit 20 holds progression of the process. Meanwhile, if the determination result of Step S90 is YES, the multi pack management unit 20 proceeds to S100.

In Step S100, the multi pack management unit 20 determines whether the parallel multi pack module MP is being discharged. To this end, the multi pack management unit 20 may monitor the measured current values (I_{pack,1} to I_{pack,n}) measured using the first to n^{th} current sensors I1 to In. If the measured current values are positive rather than 0, it may be determined that the parallel multi pack module MP is being discharged.

If the determination result of Step S100 is NO, the multi pack management unit 20 ends the execution of the power control method according to an embodiment of the present disclosure. Meanwhile, if the determination result of Step S100 is YES, the multi pack management unit 20 proceeds to Step S20. Therefore, the process of calculating the total power (Pₜₒₜₐₗ) of the parallel multi pack module MP and the process of controlling the discharging of the parallel multi pack module MP so as not to exceed the calculated total power (Pₜₒₜₐₗ) are repeated again.

Meanwhile, the power control method described above relates to a case where the parallel multi pack module MP is discharged. However, it is obvious to those skilled in the art that the present disclosure may also be applied even when the parallel multi pack module MP is being charged using a charging device.

According to the present disclosure, the total power of the parallel multi pack module is adjusted so that the pack power of the battery pack having a lowest resistance among the battery packs included in the parallel multi pack module becomes identical to a minimum available power among available powers of the battery packs, thereby fundamentally preventing the battery pack having a low resistance from being overcharged or overdischarged. As a result, safety and reliability of the parallel multi pack module may be improved compared to the prior art.

In the description of the various exemplary embodiments of the present disclosure, it should be understood that the element referred to as ‘unit’ is distinguished functionally rather than physically. Therefore, each element may be selectively integrated with other elements or each element may be divided into sub-elements for effective implementation control logic (s). However, it is obvious to those skilled in the art that, if functional identity can be acknowledged for the integrated or divided elements, the integrated or divided elements fall within the scope of the present disclosure.

The present disclosure has been described in detail. However, it should be understood that the detailed description and specific examples, while indicating preferred embodiments of the disclosure, are given by way of illustration only, since various changes and modifications within the scope of the disclosure will become apparent to those skilled in the art from this detailed description.

1. An apparatus for controlling a power of a parallel multi pack module, comprising:
first to n^{th} sensor circuits respectively configured to measure operation characteristic values including measured current values of first to n^{th} battery packs that are included in the parallel multi pack module and connected to each other in parallel;
a power management circuit configured to control a power consumed in a load or a power provided to the parallel multi pack module by a charging device to correspond to a total power of the parallel multi pack module; and
a multi pack management circuit operatively coupled to the first to n^{th} sensor circuits and the power management circuit,
wherein the multi pack management circuit is configured to determine a minimum available power of the first to n^{th} battery packs based on the operation characteristic values of the first to n^{th} battery packs respectively received from the first to n^{th} sensor circuits, to determine a total power of the parallel multi pack module from the minimum available power and a ratio of a summed current value to a maximum current value among the measured current values of the first to n^{th} battery packs, and to transmit the determined total power of the parallel multi pack module to the power management circuit, and
wherein the power management circuit is configured to control the power consumed in the load or the power provided to the parallel multi pack module by the charging device to correspond to the total power of the parallel multi pack module.

2. The apparatus for controlling power of a parallel multi pack module according to claim 1,
wherein the operation characteristic values further include measured voltage values of the first to n^{th} battery packs, and
the multi pack management circuit is further configured to:
determine pack resistances of the first to n^{th} battery packs, respectively, from the measured current values and the measured voltage values of the first to n^{th} battery packs,
determine an available power corresponding to the pack resistance with reference to a predetermined pack resistance-available power look-up table for each battery pack, and
determine a minimum value among the available powers as the minimum available power.

3. The apparatus for controlling power of a parallel multi pack module according to claim 2,
wherein the multi pack management circuit is further configured to:
periodically receive a measured voltage value and a measured current value of each battery pack from a corresponding one of the first to n^{th} sensor circuits, and
determine an average ratio of a voltage change to a current change calculated from the measured current values and the measured voltage values of the first to n^{th} battery packs by means of linear regression analysis as the pack resistance of the first to n^{th} battery packs.

4. The apparatus for controlling power of a parallel multi pack module according to claim 1,
wherein the multi pack management circuit is further configured to:
determine a state of charge (SOC) of each of the first to n^{th} battery packs based on the operation characteristic value of each battery pack received from a corresponding one of the first to n^{th} sensor circuits,
determine an available power corresponding to the SOC of each of the first to n^{th} battery packs with reference to a predefined SOC-available power look-up table, and
determine a minimum value among the available powers as the minimum available power.

5. The apparatus for controlling power of a parallel multi pack module according to claim 1,
wherein the multi pack management circuit is configured to calculate the total power (Pₜₒₜₐₗ) of the parallel multi pack module using the following equation:
Pₜₒₜₐₗ=min(P_{pack,k})*Iₜₒₜₐₗ/max(I_{pack,k}),
wherein k is an integer from 1 to n; min(P_{pack,k}) corresponds to a minimum available power among the available powers of the first to n^{th} battery packs; Iₜₒₜₐₗ corresponds to a summed current value for the measured current values of the first to n^{th} battery packs; and max(I_{pack,k}) corresponds to a maximum current value among the measured current values of the first to n^{th} battery packs.

6. The apparatus for controlling power of a parallel multi pack module according to claim 1, further comprising:
a communication circuit interposed between the multi pack management circuit and the power management circuit.

7. The apparatus for controlling power of a parallel multi pack module according to claim 6,
wherein the parallel multi pack module is mounted to an electric-driven vehicle, and
the power management circuit is included in a control system of the electric-driven vehicle.

8. A battery management system, comprising the apparatus for controlling power of a parallel multi pack module according to claim 1.

9. An electric driving mechanism, comprising the apparatus for controlling power of a parallel multi pack module according to claim 1.

10. A method for controlling a power of a parallel multi pack module, the method comprising:
(a) measuring operation characteristic values including measured current values of first to n^{th} battery packs that are included in the parallel multi pack module and connected to each other in parallel;
(b) determining an available power of each of the first to n^{th} battery packs based on the measured operation characteristic value of a corresponding one of the battery packs;
(c) determining a minimum available power among the available powers of the first to n^{th} battery packs;
(d) determining a total power of the parallel multi pack module from the minimum available power and a ratio of a summed current value to a maximum current value among the measured current values of the first to n^{th} battery packs; and
(e) controlling charging or discharging of the first to n^{th} battery packs to correspond to the total power of the parallel multi pack module.

11. The method for controlling power of a parallel multi pack module according to claim 10,
wherein the operation characteristic values further include measured voltage values of the first to n^{th} battery packs, and
wherein the step (b) includes:
determining pack resistances of the first to n^{th} battery packs respectively from the measured current values and the measured voltage values of the first to n^{th} battery packs,
determining an available power corresponding to the pack resistance with reference to a predetermined pack resistance-available power look-up table for each battery pack, and
determining a minimum value among the available powers as the minimum available power.

12. The method for controlling power of a parallel multi pack module according to claim 11,
wherein the step (b) further includes:
periodically receiving a measured voltage value and a measured current value of each battery pack from first to n^{th} sensor circuits, and
determining an average ratio of a voltage change to a current change calculated from the measured current values and the measured voltage values of the first to n^{th} battery packs by means of linear regression analysis as the pack resistance of the first to n^{th} battery packs.

13. The method for controlling power of a parallel multi pack module according to claim 10,
wherein the step (b) includes:
determining a state of charge (SOC) of each of the first to n^{th} battery packs based on the measured operation characteristic value of a corresponding one of the battery packs,
determining an available power corresponding to the SOC of each of the first to n^{th} battery packs with reference to a predefined SOC-available power look-up table, and
determining a minimum value among the available powers as the minimum available power.

14. The method for controlling power of a parallel multi pack module according to claim 10,
wherein in the step (d), the total power (Pₜₒₜₐₗ) of the parallel multi pack module is calculated using the following equation:
Pₜₒₜₐₗ=min(P_{pack,k})*Iₜₒₜₐₗ/max(I_{pack,k}),
wherein k is an integer from 1 to n; min(P_{pack,k}) corresponds to a minimum available power among the available powers of the first to n^{th} battery packs; Iₜₒₜₐₗ corresponds to a summed current value for the measured current values of the first to n^{th} battery packs; and max(I_{pack,k}) corresponds to a maximum current value among the measured current values of the first to n^{th} battery packs.
